(19) United States
(12) Patent Application Publication
(10) Pub. No.: US 2009/0115310 A1
(43) Pub. Date: May 7, 2009

(54) COATING LIQUID FOR HOLE INJECTION AND TRANSPORT LAYER, PRODUCTION METHOD OF HOLE INJECTION AND TRANSPORT LAYER, ORGANIC ELECTROLUMINESCENT ELEMENT, AND PRODUCTION METHOD THEREOF

(75) Inventor: Emi Yamamoto, Nara (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 11/916,330

(22) PCT Filed: Jun. 1, 2006
(86) PCT No.: PCT/JP2006/311001

§ 371 Date: Dec. 3, 2007

(30) Foreign Application Priority Data
Jun. 6, 2005 (JP) 2005-165929

(51) Int. Cl. H01J 1/62; C08G 75/06; B05D 5/12

(52) U.S. Cl. 313/498; 525/186; 427/66

(57) ABSTRACT

A coating liquid for hole injection and transport layers improves the injecting property of the coating liquid when it is injected by an injection device and light-emitting uniformity of an organic electroluminescent element, reduces leak current, and improves light-emitting efficiency. The coating liquid for hole injection and transport layers is a coating liquid for hole injection and transport layers in an organic electroluminescent element, wherein the coating liquid for hole injection and transport layers contains poly(3,4-ethylenedioxythiophene), polystyrene sulfonate, and (poly)alkylene glycol alkyl ether.

### BACKGROUND OF THE INVENTION

1. Field of the Invention

The present invention relates to coating liquids for hole injection and transport layers, production methods of hole injection and transport layers, organic electroluminescent elements, and production methods of the organic electroluminescent elements. More specifically, the present invention relates to a coating liquid for hole injection and transport layers, preferably used for forming a hole injection and transport layer in an injection device such as an ink-jet device, a production method of a hole injection and transport layer using such a coating liquid, an organic electroluminescent element including a hole injection and transport layer formed by such a production method, and a production method of the organic electroluminescent element.

2. Description of the Related Art

Hole injection and transport layers are formed between a positive electrode and a light-emitting layer in order to improve light-emitting efficiency and durability of organic electroluminescent elements. Characteristics such as light-emitting efficiency and durability are important for the spread of organic electroluminescent elements. Therefore, improvement in performances of the hole injection and transport layers are needed. A deposition process and a wet process are mentioned as a method for forming such hole injection and transport layers, and a wet process is generally used in view of production costs. Polymer materials are generally mentioned as a material for hole injection and transport layers capable of being formed by a wet process. Such materials are insufficient in basic performances such as injecting property and uneven light emission. Further, such materials have conductivity, and therefore leak current may be generated when a low voltage is applied between electrodes formed with the hole injection and transport layer therebetween if patterning is not completely performed. As a result, a desired light-emitting pattern may not be obtained. In order to produce high-definition organic electroluminescent elements, the hole positive-injecting and transporting layers need to be formed by fine patterning.

For this problem, a method for applying a coating liquid for hole injection and transport layers, which is prepared by dispersing or dissolving a material used as a hole injection and transport layer into water, with an ink-jet device, was proposed as a method for forming such a hole injection and transport layer (for example, refer to Japanese Kokai Publication No. 2000-106278 and Japanese Kokai Publication No. 2004-31363). However, if the coating liquid for hole injection and transport layers including only the material used as a hole injection and transport layer and water is applied by an ink-jet device, water as a solvent vaporizes at a head of the ink-jet device, and therefore the material (solute) used as the hole injection and transport layer is deposited. Therefore, the uniformity of the hole injection and transport layer after the coating liquid is dried is insufficient. In this point, such a method has room for improvement.

In order to adjust physical values of the coating liquid for hole injection and transport layers, such as a contact angle, a viscosity, a surface tension, a method of applying, with an ink-jet method, a coating liquid for hole injection and transport layers prepared by mixing an alcohol or a solvent having a high boiling point with a material used as a hole injection and transport layer was proposed. In this case, high-definition patterning can be performed because the injection can be controlled precisely. However, in comparison to the coating liquid for hole injection and transport layers including only the material used as the hole injection and transport layer and water, this coating liquid for hole injection and transport layers causes much leak current between electrodes formed with the hole injection and transport layer therebetween, which causes defects, and for example, constant current driving can not be performed. In addition, the light-emitting efficiency is also reduced. In these points, such a method has room for improvement.

For this problem, a method of reducing leak current by forming a hole injection and transport layer using a coating liquid for hole injection and transport layers containing a surfactant was proposed (for example, refer to Japanese Kokai Publication No. 2005-5020). However, the surfactant remains inside the hole injection and transport layer even after completion of an organic electroluminescent element, and therefore the light-emitting efficiency of the element is reduced. In this point, the method has room for improvement.

### SUMMARY OF THE INVENTION

In order to overcome the problems described above, preferred embodiments of the present invention a coating liquid for hole injection and transport layers, which can improve injecting property of the coating liquid when injected by an injection device and light-emitting uniformity of an organic electroluminescent element, reduce leak current, and improve light-emitting efficiency.

The present inventors made various investigations concerning a coating liquid for hole injection and transport layers including, as a main solvent, water containing a mixture of poly (3,4-ethylenedioxythiophene) and polystyrene sulfonate which are used as a hole injection and transport layer. The inventors noted (poly) alkylene glycol alkyl ether as a compound which can be contained in the coating liquid for hole injection and transport layers. The inventors discovered that if (poly)alkylene glycol alkyl ether is contained in the coating liquid for hole injection and transport layers, injecting property of the coating liquid for hole injection and transport layers when injected by an injection device and light-emitting uniformity of an organic electroluminescent element including a hole injection and transport layer formed using the coating liquid for hole injection and transport layers can be improved. Further, the inventors discovered that if diethylene glycol monopropyl ether and the like is contained in the coating liquid for hole injection and transport layers, the injecting property of the coating liquid for hole injection and transport layers when injected by an injection device and light-emitting uniformity of an organic electroluminescent element including a hole injection and transport layer formed using the coating liquid for hole injection and transport layers can be improved and in addition, leak current can be reduced and light-emitting efficiency can be improved. As a result, the above-mentioned problems have been solved, leading to completion of preferred embodiments of the present invention.

That is, preferred embodiments of the present invention provide a coating liquid for hole injection and transport layers in an organic electroluminescent element, wherein the coating liquid for hole injection and transport layers contains poly(3,4-ethylenedioxythiophene), polystyrene sulfonate, and (poly)alkylene glycol alkyl ether.

The coating liquid for hole injection and transport layers according to a preferred embodiment of the present invention is a coating liquid which can be used for forming a hole injection and transport layer in an organic electroluminescent element including at least a hole injection and transport layer, and such a coating liquid contains a mixture of poly(3,4-ethylenedioxythiophene) with polystyrene sulfonate. The coating liquid for hole injection and transport layers according to a preferred embodiment of the present invention may contain water or a solvent such as an alcohol other than water, or may contain water and a solvent such as an alcohol other than water. The poly(3,4-ethylenedioxythiophene) and the polystyrene sulfonate are conductive polymers, and the mixture thereof is used as a hole injection and transport layer. The hole injection and transport layer formed using the coating liquid for hole injection and transport layers according to a preferred embodiment of the present invention is formed between a positive electrode and a light-emitting layer in order to improve light-emitting efficiency and durability of the organic electroluminescent element. Such a layer has a function of injecting and transporting holes from the positive electrode to the light-emitting layer. The hole injection and transport layer according to a preferred embodiment of the present invention may have only a function of injecting holes into the light emitting layer or only a function of transporting holes thereto.

The (poly)alkylene glycol alkyl ether is a compound having a chemical structure in which a hydroxyl group at the end is bonded to an alkylene group, and the alkylene group is bonded to an alkoxyl group, or a chemical structure in which a hydroxyl group at the end is bonded to an alkylene group, and the alkylene group is bonded to one or more oxyalkylene groups, and the one or more oxyalkylene groups are bonded to the alkoxyl group. The (poly)alkyleneglycol alkyl ether means polyalkylene glycol alkyl ether or alkylene glycol alkyl ether.

The coating liquid for hole injection and transport layers according to a preferred embodiment of the present invention may or may not contain other components as long as it essentially contains such components. The composition of the coating liquid is not especially limited.

According to the coating liquid for hole injection and transport layers of a preferred embodiment of the present invention, water can be used as a main solvent, and injecting property of the coating liquid when applied by an injection device such as an ink-jet device can be improved. Therefore, the hole injection and transport layer can be formed by high-definition patterning. As a result, light-emitting uniformity of an organic electroluminescent element including this hole injection and transport layer can be improved. Further, leak current of an organic electroluminescent element including the hole injection and transport layer formed using the coating liquid for hole injection and transport layers according to a preferred embodiment of the present invention, particularly leak current at a low voltage can be reduced, and light-emitting efficiency can be improved. Preferred embodiments of the coating liquid for hole injection and transport layers of the present invention are described below in more detail.

It is preferable that the (poly)alkylene glycol alkyl ether is represented by the following formula (1):

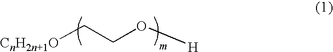

(in the formula, m is 1 to 3; n is an integer of 5 to 12 if m is 1; n is an integer of 3 to 12 if m is 2; and n is an integer of 1 to 4 if m is 3).

According to this, leak current at a low voltage in the organic electroluminescent element including the hole injection and transport layer formed using the coating liquid for hole injection and transport layers according to a preferred embodiment of the present invention can be sufficiently reduced, and in addition, the light-emitting efficiency can be significantly improved in comparison to the case where the coating liquid for hole injection and transport layers including only poly(3,4-ethylenedioxythiophene), polystyrene sulfonate, and water is used to form an organic electroluminescent element. It is more preferable that with respect to the ether compound represented by the formula (1) which is contained in the coating liquid for hole injection and transport layers according to a preferred embodiment of the present invention, n is 5 to 8 if m is 1; n is 3 to 12 if m is 2; and n is 1 if m is 3.

It is preferable that the coating liquid for hole injection and transport layers contains more than 0% by weight and about 11% by weight or less of the (poly) alkylene glycol alkyl ether represented by the formula (1). If the content of the ether compound represented by the formula (1) is more than about 11% by weight, uneven luminance which can be recognized by human eyes may be generated. This is because, among solvents contained in the coating liquid, the ether compound represented by the formula (1) has the highest boiling point, and therefore if the content of the ether compound is more than about 11% by weight, (poly) alkylene glycol alkyl ether remains after completion of the process of drying the coating liquid, which is performed immediately after coated by an injection device, and thereby the surface of the hole injection and transport layer may be roughened.

It is preferable that the content of the ether compound represented by the formula (1) in the coating liquid for hole injection and transport layers is about 5% by weight or less. If (poly)alkylene glycol alkyl ether that is a hydrophobic compound is used, a lower alcohol and the like is used for mixing the (poly) alkylene glycol alkyl ether with a mixture of poly(3,4-ethylenedioxythiophene) with polystyrene sulfonate, which is dispersed into water. The more the addition amount of the (poly)alkylene glycol alkyl ether increases, the more the addition amount of the lower alcohol and the like increases. As a result, the proportion of the alcohol having a low boiling point in the coating liquid also increases. Therefore, it becomes difficult to adjust physical values such as surface tension and viscosity when the coating liquid is prepared. Accordingly, the coating liquid can be easily adjusted to have physical values suitable for injection, if the content of the ether compound represented by the formula (1) is about 5% by weight or less.

It is more preferable that the content of the ether compound represented by the formula (1) in the coating liquid for hole injection and transport layer is more than about 2% by weight. If the content is less than about 2% by weight, the operation and effects of preferred embodiments of the present invention may be insufficiently obtained.

It is preferable that the (poly)alkylene glycol alkyl ether (ether compound) has a boiling point of about 200° C. or more at about 1.0×10⁵ Pa. Examples of such an ether compound having a boiling point of about 200° C. or more include ethylene glycol monopentyl ether, ethylene glycol monohexyl ether, ethylene glycol monoheptyl ether, ethylene glycol monooctyl ether, ethylene glycol monononyl ether, ethylene glycol monodecyl ether, ethylene glycol monoundecyl ether, ethylene glycol monododecyl ether, ethylene glycol monotetradecyl ether, diethylene glycol monopropyl ether, diethylene glycol monobutyl ether, diethylene glycol monopentyl ether, diethylene glycol monohexyl ether, diethylene glycol monoheptyl ether, diethylene glycol monooctyl ether, diethylene glycol monononyl ether, diethylene glycol monodecyl ether, diethylene glycol monoundecyl ether, diethylene glycol monododecyl ether, diethylene glycol monotetradecyl ether, triethylene glycol monomethyl ether, triethylene glycol monoethyl ether, triethylene glycol monopropyl ether, triethylene glycol monobutyl ether, and triethylene glycol monopentyl ether.

If the ether compound contained in the coating liquid for hole injection and transport layers according to a preferred embodiment of the present invention has a boiling point of less than about 200° C. at about 1.0×10⁵ Pa, the coating liquid may be clogged at an outlet of an application device. According to a preferred embodiment of the present invention, the coating liquid preferably includes the ether compound that is a solvent with a high boiling point, and therefore the ether compound is hard to vaporize when the coating liquid is applied. Therefore, the material (solute) used as the hole injection and transport layer is not deposited at a head of an injection device such as an ink-jet device, and therefore clogging of the coating liquid at the outlet of the application device is prevented. As a result, the coating liquid for hole injection and transport layer can be easily applied. Further, a step of drying the coating liquid after applied on a substrate of an organic electroluminescent element can be easily controlled. Therefore, the flatness of the hole injection and transport layer can be adjusted. As a result, the hole injection and transport layer can be uniformly formed. In addition, the leak current can be reduced and the light-emitting efficiency can be improved. It is more preferable that the ether compound contained in the coating liquid for hole injection and transport layers according to a preferred embodiment of the present invention is in the liquid state at about 1.0×10⁵ Pa and about 25° C.

It is preferable that the coating liquid for hole injection and transport layers contains a lower alcohol. Even if the ether compound contained in the coating liquid for hole injection and transport layers is a hydrophobic compound, such an ether compound is dissolved into a lower alcohol. Therefore, the ether compound is not separated from the solvent. As a result, the coating liquid for hole injection and transport layers can be applied by an injection device such as ink-jet device. In the present description, the lower alcohol means alcohols containing 1 to 8 carbon atoms.

It is preferable that the lower alcohol is selected from the group consisting of methanol, ethanol, and isopropyl alcohol. These compounds are hydrophilic alcohols, and therefore use of such alcohols makes it possible to adjust the coating liquid for hole injection and transport layers to have physical values (contact angle, viscosity, surface tension, and the like) suitable for injection when the hole injection and transport layer is formed with an injection device such as an ink-jet device. As a result, the coating liquid for hole injection and transport layers can be easily applied, and therefore a finely patterned hole injection and transport layer can be formed.

It is preferable that the (poly)alkylene glycol alkyl ether is an ether compound selected from the group consisting of diethylene glycol monopropyl ether, diethylene glycol monobutyl ether, diethylene glycol monohexyl ether, diethylene glycol monododecyl ether, ethylene glycol monopentyl ether, ethylene glycol monohexyl ether, ethylene glycol monooctyl ether, ethylene glycol monododecyl ether, and triethylene glycol monomethyl ether. These ether compounds are easily available, and therefore the hole injection and transport layer can be easily formed. These ether compounds can be easily removed from the hole injection and transport layer during a sintering process. Therefore, the leak current can be reduced and the light-emitting efficiency can be improved.

According to another preferred embodiment of the present invention, an organic electroluminescent element includes a hole injection and transport layer formed using the coating liquid for hole injection and transport layers. According to this, the leak current can be reduced and the light-emitting efficiency can be improved. Further, the organic electroluminescent element has a hole injection and transport layer with an excellent flatness, and therefore such an element has excellent light-emitting uniformity.

It is preferable that the hole injection and transport layer has a current density of about 1.0×10⁻² mA/cm² or less at an applied voltage of 1V. If the current density is more than about 1.0×10⁻² mA/cm² at an applied voltage of 1V, the holes can not be injected and transported efficiently, and therefore the light-emitting efficiency may be insufficiently improved. However, if the current density is about 1.0×10⁻² mA/cm² or less at a voltage of 1 V, the leak current at a low voltage can be reduced and the light-emitting efficiency can be improved at an equivalent or lower level in comparison to the case where the coating liquid for hole injection and transport layers including only the material used as the hole injection and transport layer and water is used. It is more preferable that the hole injection and transport layer has a current density of about 9.5×10⁻⁴ mA/cm² or less at an applied voltage of about 1V.

According to another preferred embodiment of the present invention, a method for producing a hole injection and transport layer using the coating liquid for hole injection and transport layer includes a step of forming a hole injection and transport layer by pattern printing of the coating liquid for hole injection and transport layers. According to this, a hole injection and transport layer can be uniformly formed, and the leak current at a low voltage can be reduced.

It is preferable that the pattern printing is performed with an injection device. A depression to which the coating liquid is applied is formed to have a specific pattern shape on a substrate, and then the coating liquid is applied to have the specific pattern shape by continuously injecting the coating liquid using an injection device. As a result, a finely patterned hole injection and transport layer can be easily formed at low cost.

Examples of the above-mentioned injection device include an ink-jet device, a nozzle coater, and a dispenser. The ink-jet device can be particularly preferably used. According to the ink-jet device, the coating liquid can be accurately injected into a specific fine pattern shape to which the coating liquid is applied. Therefore, a finely patterned hole injection and transport layer can be easily formed at low costs.

It is preferable that in the step of forming the hole injection and transport layer, one or a combination of natural drying, heating, pressurization, and depressurization is performed after the coating liquid for hole injection and transport layers is applied. According to this, uneven film thickness or phase separation of the solute can be prevented and the hole injection and transport layer can be uniformly and homogeneously formed. The flatness of the hole injection and transport layer can be controlled by a method of removing the solvent contained in the coating liquid.

Another preferred embodiment of the present invention provides a method for producing an organic electroluminescent element including a hole injection and transport layer formed by the method for producing the hole injection and transport layer. According to this, the leak current at a low voltage can be reduced and an organic electroluminescent element having improved light-emitting efficiency can be produced.

According to the coating liquid for hole injection and transport layers according to various preferred embodiments of the present invention, the injecting property of the coating liquid when injected by an injection device and light-emitting uniformity can be improved. In addition, leak current at a low voltage can be reduced and light-emitting efficiency can be improved.

Other features, elements, processes, steps, characteristics and advantages of the present invention will become more apparent from the following detailed description of preferred embodiments of the present invention with reference to the attached drawings.

### DETAILED DESCRIPTION OF PREFERRED EMBODIMENTS

The present invention is described below in more detail with reference to preferred embodiments thereof, but not limited to only these preferred embodiments. The term “%” represents “% by weight”, unless otherwise specified, in the present preferred embodiments.

### Preferred Embodiment 1

A method of preparing an organic electroluminescent element according to the first preferred embodiment will now be described.

First, an ITO (Indium Tin Oxide) film with a thickness of, for example, about 150 nm formed on a glass substrate was patterned by a photolithography method, and thereby a glass substrate with stripe-shaped ITO transparent electrodes was prepared. The stripe-shaped ITO transparent electrodes serve as a positive electrode in an organic electroluminescent element. Then, a non-photosensitive polyimide film was formed by patterning to fill a space between the stripe-shaped ITO transparent electrodes, thereby forming a bank. Then, this substrate was washed by a wet process using isopropyl alcohol, acetone, purified water, and the like, and a dry process such as an UV/ozone treatment and a plasma treatment.

Then, a coating liquid for hole injection and transport layers 1 containing, for example, about 30% of an approximately 1% aqueous dispersion of poly(3,4-ethylenedioxythiophene) and polystyrene sulfonate, about 20% of ethanol, about 2% of diethylene glycol monopropyl ether, and about 48% of water was prepared. In the approximately 1% aqueous dispersion of poly(3,4-ethylenedioxythiophene) and polystyrene sulfonate, a ratio by weight of poly(3,4-ethylenedioxythiophene) to polystyrene sulfonate is preferably about 1 to 20, and a total content of poly(3,4-ethylenedioxythiophene) and polystyrene sulfonate accounts for approximately 1% relative to the entire of the aqueous dispersion.

Then, the coating liquid for hole injection and transport layers 1 was injected with an ink-jet device. Then, the substrate was dried under reduced pressure for approximately 60 minutes at a room temperature (about 25° C.) and then dried by heating for approximately 60 minutes at about 200° C., for example, and thereby the solvent was removed. As a result, a hole injection and transport layer was formed.

Then, using the ink-jet device, a PDF (poly(9,9-dioctylfluorene)) that is a material for a light-emitting layer was injected on the hole injection and transport layer. Then, the substrate was dried under reduced pressure for approximately 60 minutes at a room temperature (about 25° C.) and heated for approximately 60 minutes at about 200° C., for example. As a result, a light-emitting layer was formed.

On this light-emitting layer, a shadow mask was fixed and arranged to be perpendicular to the stripe-shaped ITO electrodes. Then, calcium (Ca) was deposited to have a thickness of, for example, about 5 nm inside a vacuum deposition device, and then aluminum (Al) was deposited to have a thickness of about 100 nm, for example. As a result, negative electrodes were formed. Finally, a glass for sealing was attached to the substrate, and thereby a bottom emission organic electroluminescent element was prepared.

### Preferred Embodiment 2

An organic electroluminescent element was prepared in the same manner as in Preferred Embodiment 1, except that a coating liquid for hole injection and transport layers 2 containing about 2% of diethylene glycol monohexyl ether instead of diethylene glycol monopropyl ether was used.

### Preferred Embodiment 3

An organic electroluminescent element was prepared in the same manner as in Preferred Embodiment 1, except that a coating liquid for hole injection and transport layers 3 containing about 2% of diethylene glycol monododecyl ether instead of diethylene glycol monopropyl ether was used.

### Preferred Embodiment 4

An organic electroluminescent element was prepared in the same manner as in Preferred Embodiment 1, except that a coating liquid for hole injection and transport layers 4 containing about 2% of triethylene glycol monomethyl ether instead of diethylene glycol monopropyl ether was used.

### Preferred Embodiment 5

An organic electroluminescent element was prepared in the same manner as in Preferred Embodiment 1, except that a coating liquid for hole injection and transport layers 5 containing about 2% of triethylene glycol monobutyl ether instead of diethylene glycol monopropyl ether was used.

### Preferred Embodiment 6

An organic electroluminescent element was prepared in the same manner as in Preferred Embodiment 1, except that a coating liquid for hole injection and transport layers 6 containing about 2% of ethylene glycol monopentyl ether instead of diethylene glycol monopropyl ether was used.

### Preferred Embodiment 7

An organic electroluminescent element was prepared in the same manner as in Preferred Embodiment 1, except that a coating liquid for hole injection and transport layers 7 containing about 2% of ethylene glycol monooctyl ether instead of diethylene glycol monopropyl ether was used.

### Preferred Embodiment 8

An organic electroluminescent element was prepared in the same manner as in Preferred Embodiment 1, except that a coating liquid for hole injection and transport layers 8 containing about 2% of ethylene glycol monododecyl ether instead of diethylene glycol monopropyl ether was used.

### Preferred Embodiment 9

An organic electroluminescent element was prepared in the same manner as in Preferred Embodiment 1, except that a coating liquid for hole injection and transport layers 9 containing about 2% of diethylene glycol monoethyl ether instead of diethylene glycol monopropyl ether was used.

### Preferred Embodiment 10

An organic electroluminescent element was prepared in the same manner as in Preferred Embodiment 1, except that a coating liquid for hole injection and transport layers 10 containing about 2% of diethylene glycol monotetradecyl ether instead of diethylene glycol monopropyl ether was used.

### Preferred Embodiment 11

An organic electroluminescent element was prepared in the same manner as in Preferred Embodiment 1, except that a coating liquid for hole injection and transport layers 11 containing about 2% of triethylene glycol monohexyl ether instead of diethylene glycol monopropyl ether was used.

### Preferred Embodiment 12

An organic electroluminescent element was prepared in the same manner as in Preferred Embodiment 1, except that a coating liquid for hole injection and transport layers 12 containing about 2% of ethylene glycol monobutyl ether instead of diethylene glycol monopropyl ether was used.

### Preferred Embodiment 13

An organic electroluminescent element was prepared in the same manner as in Preferred Embodiment 1, except that a coating liquid for hole injection and transport layers 13 containing about 2% of ethylene glycol monotetradecyl ether instead of diethylene glycol monopropyl ether was used.

### Preferred Embodiment 14

An organic electroluminescent element was prepared in the same manner as in Preferred Embodiment 1, except that a coating liquid for hole injection and transport layers 14 containing about 11% of diethylene glycol monopropyl ether was used.

The content of water was adjusted in accordance with the content of the diethylene glycol monopropyl ether.

### Preferred Embodiment 15

An organic electroluminescent element was prepared in the same manner as in Preferred Embodiment 1, except that a coating liquid for hole injection and transport layers 15 containing about 5% of diethylene glycol monohexyl ether instead of diethylene glycol monopropyl ether was used.

The content of water was adjusted in accordance with the content of the diethylene glycol monohexyl ether.

### Preferred Embodiment 16

An organic electroluminescent element was prepared in the same manner as in Preferred Embodiment 1, except that a coating liquid for hole injection and transport layers 16 containing about 8% of diethylene glycol monohexyl ether instead of diethylene glycol monopropyl ether was used.

The content of water was adjusted in accordance with the content of the diethylene glycol monohexyl ether.

### Preferred Embodiment 17

An organic electroluminescent element was prepared in the same manner as in Preferred Embodiment 1, except that a coating liquid for hole injection and transport layers 17 containing about 11% of diethylene glycol monohexyl ether instead of diethylene glycol monopropyl ether was used.

The content of water was adjusted in accordance with the content of the diethylene glycol monohexyl ether.

### Preferred Embodiment 18

An organic electroluminescent element was prepared in the same manner as in Preferred Embodiment 1, except that a coating liquid for hole injection and transport layers 18 containing about 15% of diethylene glycol monohexyl ether instead of diethylene glycol monopropyl ether was used.

The content of water was adjusted in accordance with the content of the diethylene glycol monohexyl ether.

### Comparative Preferred Embodiment 1

An organic electroluminescent element was prepared in the same manner as in Preferred Embodiment 1, except that a coating liquid for hole injection and transport layers 19 not containing diethylene glycol monopropyl ether and ethanol was used.

The content of water was adjusted in accordance with no addition of diethylene glycol monopropyl ether and ethanol.

### Comparative Preferred Embodiment 2

An organic electroluminescent element was prepared in the same manner as in Preferred Embodiment 1, except that a coating liquid for hole injection and transport layers 20 containing about 2% of ethylene glycol (having a boiling point of about 198° C. at about 1.0×10⁵ Pa) instead of diethylene glycol monopropyl ether was used.

### Evaluation 1

Coating liquids for hole injection and transport layers prepared in Preferred Embodiments 1 to 14 and Comparative Preferred Embodiments were evaluated for injecting property when applied by an ink-jet device, uneven light emission of a prepared organic electroluminescent element, a current density [mA/cm²] of a hole injection and transport layer at an applied voltage of 1 V, and a light-emitting efficiency [cd/A] when an organic electroluminescent element emits light at 500 cd/m².

The following Table 1 shows the results.

TABLE 1

| | | | | Current density at | Luminance ratio |
|---|---|---|---|---|---|
| | Coating | Injecting | Uneven light | 1 V | at 500 cd/m² |
| | liquid | property | emission | [mA/cm²] | [cd/A] |
| Embodiment 1 | 1 | Excellent | Excellent | 9.4E−04 | 13.7 |
| Embodiment 2 | 2 | Excellent | Excellent | 9.6E−06 | 15.4 |
| Embodiment 3 | 3 | Excellent | Excellent | 9.8E−05 | 14.0 |
| Embodiment 4 | 4 | Excellent | Excellent | 9.1E−04 | 12.9 |
| Embodiment 5 | 5 | Excellent | Excellent | 1.1E−05 | 11.3 |
| Embodiment 6 | 6 | Excellent | Excellent | 7.9E−06 | 15.1 |
| Embodiment 7 | 7 | Excellent | Excellent | 1.2E−05 | 14.2 |
| Embodiment 8 | 8 | Excellent | Excellent | 1.2E−05 | 12.9 |
| Embodiment 9 | 9 | Good | Good | 4.5E−02 | 8.1 |
| Embodiment 10 | 10 | Excellent | Excellent | 8.4E−05 | 6.1 |
| Embodiment 11 | 11 | Excellent | Excellent | 9.3E−05 | 3.9 |
| Embodiment 12 | 12 | Good | Poor | 1.1E−02 | 8.3 |
| Embodiment 13 | 13 | Excellent | Excellent | 8.9E−05 | 5.8 |
| Embodiment 14 | 14 | Excellent | Excellent | 1.4E−05 | 10.4 |
| Comparative | 19 | Bad | Bad | 9.7E−04 | 10.0 |
| Embodiment 1 | | | | | |
| Comparative | 20 | Poor | Excellent | 5.7E−02 | 7.4 |
| Embodiment 2 | | | | | |

In Table 1, the coating liquids 1 to 14, 19 and 20 represent the coating liquids for hole injection and transport layers 1 to 14, 19 and 20 prepared in Preferred Embodiments and Comparative Preferred Embodiments.

With respect to the injecting property, the coating liquids were subjected to an injecting test 3000 times. The coating liquids were evaluated as excellent if no injecting defects were generated after 3000 times of the injecting test; the coating liquids were evaluated as good if injecting defects were generated during 1000 to 3000 times of the injecting test; and the coating liquids were evaluated as poor if injecting defects were generated during 500 to 1000 times of the injecting test; and the coating liquids were evaluated as bad if injecting defects were generated before 500 times of the injecting test. In the injecting test, ahead from which about 8 pl of the coating liquid is injected at each injection was used, and based on whether or not the coating liquid was stably injected without being clogged at the head of the ink-jet device, the evaluation was determined.

With respect to the uneven light emission, the coating liquids were evaluated as excellent if a difference in luminance between the highest luminance and the lowest luminance of an organic electroluminescent element was about 15% or less; the coating liquids were evaluated as good if the difference is from about 15% to about 20%; the coating liquids were evaluated as poor if the difference is from about 20% to about 30%; and the coating liquids were evaluated as bad if the difference is about 30% or more.

As shown in Table 1, the injecting property in Preferred Embodiments 1 to 14 where the coating liquids 1 to 14 were applied with an ink-jet device was more improved than that in Comparative Preferred Embodiments 1 and 2. In organic electroluminescent elements prepared in Preferred Embodiments 1 to 8, 10, 11, 13, and 14, uneven light emission as an index of ununiformity of the hole injection and transport layer was hardly generated, and the leak current at a low voltage can be reduced at an equivalent or higher level than that in Comparative Preferred Embodiment 1. Further, in Preferred Embodiments 1 to 8, the light-emitting efficiency was more improved than that in Comparative Preferred Embodiment 1 or 2. In Comparative Preferred Embodiment 2, the leak current was not reduced and further, the light-emitting efficiency was reduced.

### Evaluation 2

Organic electroluminescent elements obtained by applying the coating liquids for hole injection and transport layers 2 and 15 to 19 having different contents of diethylene glycol monohexyl ether, prepared in Preferred Embodiments 2 and 15 to 18, and Comparative Preferred Embodiment 2 were compared with one another in terms of a current density [mA/cm²] of the hole injection and transport layer at an applied voltage of 1V, a light-emitting efficiency [cd/A] when the element emits light at 500 cd/m², and a luminance at an applied voltage of 4V. The following Table 2 shows the results.

TABLE 2

| | | Diethylene glycol | Current density | Light-emitting | |
|---|---|---|---|---|---|
| | Coating | monohexylether | at 1 V | efficiency at | Luminance |
| | liquid | [% by weight] | [mA/cm²] | 500 cd/m² [cd/A] | ratio at 4 V |
| Comparative | 19 | 0 | 9.7E−04 | 10.0 | 0.58 |
| Embodiment 1 | | | | | |
| Embodiment 2 | 2 | 2 | 9.6E−06 | 15.4 | 1 |
| Embodiment 15 | 15 | 5 | 1.0E−05 | 14.8 | 0.88 |
| Embodiment 16 | 16 | 8 | 9.2E−06 | 15.0 | 0.9 |
| Embodiment 17 | 17 | 11 | 8.9E−06 | 13.3 | 0.75 |
| Embodiment 18 | 18 | 15 | 9.9E−06 | 12.1 | 0.71 |

In Table 2, the coating liquids 2 and 15 to 19 represent the coating liquids for hole injection and transport layers 2 and 15 to 19 prepared in Preferred Embodiments and Comparative Preferred Embodiments, respectively. With respect to the luminance ratio at about 4V, luminances at an applied voltage of about 4V of the organic electroluminescent elements prepared in Preferred Embodiments other than Embodiment 2 are represented by a ratio to the luminance at an applied voltage of about 4V of the organic electroluminescent element prepared using the coating liquid 2 in Preferred Embodiment 2.

As shown in Table 2, the organic electroluminescent elements in which the leak current was smaller and the light-emitting efficiency was higher could be prepared in the cases where the coating liquids 2 and 15 to 18 containing diethylene glycol monohexyl ether were applied by the ink-jet device, in comparison to the case where the coating liquid 19 not containing diethylene glycol monohexyl ether was applied.

In the case where the coating liquid 18 was used, effects such as improvement in the leak current value, the light-emitting efficiency, and the luminance at an applied voltage of about 4V were observed in comparison to the case where coating liquid 19 not containing diethylene glycol monohexyl ether was used. However, the degree of improvement in the leak current, the light-emitting efficiency, and the luminance at an applied voltage of about 4V is smaller in comparison to the cases where the coating liquids 2 and 15 to 17 were used. Further, if the luminance is reduced by about 25%, reduction in luminance can be recognized by human eyes, and therefore, the coating liquids 2 and 15 to 17 in which reduction in luminance at an applied voltage of about 4V accounts for less than about 25% to the highest luminance (Preferred Embodiment 2) are particularly preferable. Thus, it is preferable that the ether compound contained in the coating liquid for hole injection and transport layers of the present invention is more than 0% by weight and about 11% by weight or less.

In the case where the coating liquid 2 was applied, particularly excellent results were obtained, which shows that the content of the ether compound in the coating liquid for hole injection and transport layers of the present invention is more preferably more than about 2% by weight and about 5% by weight or less.

This Non-provisional application claims priority (under the Paris Convention and the domestic law in the country to be entered into national phase) to Patent Application No. 2005-165929 filed in Japan on Jun. 6, 2005, the entire contents of which are hereby incorporated by reference.

The terms “or more” or “or less” used in the present application include the value described. That is, the term “or more” includes the value described and values more than the value.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-14. (canceled)

15. A coating liquid for hole injection and transport layers in an organic electroluminescent element, wherein the coating liquid for hole injection and transport layers contains poly(3,4-ethylenedioxythiophene), polystyrene sulfonate, and (poly)alkylene glycol alkyl ether.

16. The coating liquid for hole injection and transport layers according to claim 15, wherein the (poly)alkylene glycol alkyl ether is represented by the following formula 1: 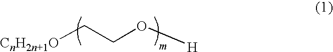
wherein in the formula, m is 1 to 3; n is an integer of 5 to 12 if m is 1; n is an integer of 3 to 12 if m is 2; and n is an integer of 1 to 4 if m is 3.

17. The coating liquid for hole injection and transport layers according to claim 16, comprising more than 0% by weight and about 11% by weight or less of the (poly)alkylene glycol alkyl ether represented by the formula 1.

18. The coating liquid for hole injection and transport layers according to claim 15, wherein the (poly)alkylene glycol alkyl ether has a boiling point of about 200° C. or more at about 1.0×10⁵ Pa.

19. The coating liquid for hole injection and transport layers according to claim 15, comprising a lower alcohol.

20. The coating liquid for hole injection and transport layers according to claim 19, wherein the lower alcohol is selected from the group consisting of methanol, ethanol, and isopropyl alcohol.

21. The coating liquid for hole injection and transport layers according to claim 15, wherein the (poly)alkylene glycol alkyl ether is an ether compound selected from the group consisting of diethylene glycol monopropyl ether, diethylene glycol monobutyl ether, diethylene glycol monohexyl ether, diethylene glycol monododecyl ether, ethylene glycol monopentyl ether, ethylene glycol monohexyl ether, ethylene glycol monooctyl ether, ethylene glycol monododecyl ether, and triethylene glycol monomethyl ether.

22. An organic electroluminescent element comprising a hole injection and transport layer formed using the coating liquid for hole injection and transport layers according to claim 15.

23. The organic electroluminescent element according to claim 22, wherein the hole injection and transport layer has a current density of about 1.0×10-2 mA/cm2 or less at an applied voltage of about 1 V.

24. A method for producing a hole injection and transport layer using the coating liquid for hole injection and transport layers of claim 15, wherein the method comprises a step of forming a hole injection and transport layer by pattern printing of the coating liquid for hole injection and transport layers.

25. The method for producing the hole injection and transport layer according to claim 24, wherein the pattern printing is performed with an injection device.

26. The method for producing the hole injection and transport layer according to claim 25, wherein the injection device is an ink-jet device.

27. The method for producing the hole injection and transport layer according to claim 24, wherein in the step of forming the hole injection and transport layer, one or a combination of natural drying, heating, pressurization, and depressurization is performed after the coating liquid for hole injection and transport layers is applied.

28. A method for producing an organic electroluminescent element including a hole injection and transport layer formed by the method for producing the hole injection and transport layer according to claim 24.
